(19) United States
(12) Patent Application Publication
(10) Pub. No.: US 2026/0229480 A1
(43) Pub. Date: Aug. 6, 2026

(54) NEGATIVE ELECTRODE FOR RECHARGEABLE LITHIUM BATTERY, RECHARGEABLE LITHIUM BATTERY INCLUDING THE SAME, AND METHOD FOR MANUFACTURING THE SAME

(71) Applicant: SAMSUNG SDI CO., LTD., Yongin-si (KR)

(72) Inventor: JeongJoo PARK, Yongin-si (KR)

(73) Assignee: SAMSUNG SDI CO., LTD., Yongin-si (KR)

(21) Appl. No.: 19/454,535

(22) Filed: Jan. 21, 2026

(30) Foreign Application Priority Data
Feb. 4, 2025 (KR) 10-2025-0013601

(51) Int. Cl. H01M 4/04; G03F 7/039; G03F 7/16; H01M 4/02; H01M 4/133; H01M 4/1393; H01M 10/0525

(52) U.S. Cl. CPC H01M 4/0404; G03F 7/0392; G03F 7/168; H01M 4/0435; H01M 4/133; H01M 4/1393; H01M 10/0525; H01M 2004/021; H01M 2004/027

(57) ABSTRACT

The present disclosure relates to a negative electrode for a rechargeable lithium battery, a rechargeable lithium battery including the negative electrode, and a method for manufacturing a negative electrode for a rechargeable lithium battery. The negative electrode includes a negative electrode current collector, a negative electrode active material layer on the negative electrode current collector, and photoresist particles on a surface of the negative electrode active material layer. The negative electrode active material layer includes a negative pattern formed on an upper portion of the negative electrode active material layer.

### CROSS-REFERENCE TO RELATED APPLICATION

This U.S. non-provisional application claims priority under 35 U.S.C. § 119 to Korean Patent Application No. 10-2025-0013601 filed on Feb. 4, 2025 in the Korean Intellectual Property Office, the disclosure of which is hereby incorporated by reference in its entirety.

### BACKGROUND

The present disclosure relates to a negative electrode for a rechargeable lithium battery and a rechargeable lithium battery including the negative electrode, and more particularly, to a negative electrode using a photoresist, a rechargeable lithium battery containing the negative electrode, and a method for manufacturing a negative electrode for a rechargeable lithium battery.

The rechargeable lithium battery generally includes a positive electrode, a negative electrode, and an electrolyte. Both the positive and negative electrodes contain active materials capable of lithium-ion intercalation and deintercalation. Electrical energy is generated through oxidation and reduction reactions as lithium ions move between the electrodes during charging and discharging.

### SUMMARY

Some example embodiments of the present disclosure include an electrode for a rechargeable lithium battery that includes a negative pattern on the negative electrode active material layer to reduce the ion resistance of lithium ions, and a rechargeable lithium battery including the electrode.

Some example embodiments of the present disclosure include a negative electrode for a rechargeable lithium battery, in which the formation of a photoresist layer reduces or suppresses the detachment of an active material during a negative patterning process, thereby improving safety and capacity retention.

According to an example embodiment of the present disclosure, a method for manufacturing a negative electrode for a rechargeable lithium battery may comprise: forming a negative electrode active material layer on a negative electrode current collector; forming a photoresist layer on the negative electrode active material layer; performing a negative patterning process on the photoresist layer to form a negative pattern on the negative electrode active material layer; and selectively removing the photoresists layer.

According to an example embodiment of the present disclosure, a negative electrode for a rechargeable lithium battery may comprise: a negative electrode current collector; and a negative electrode active material layer on the negative electrode current collector. The negative electrode active material layer may include photoresist particles on a surface thereof, and include a negative pattern formed on an upper portion of the negative electrode active material layer.

According to an example embodiment of the present disclosure, a rechargeable lithium battery may comprise: a positive electrode; the negative electrode; and a separator between the positive electrode and the negative electrode. The negative electrode may include a negative electrode current collector and negative electrode active material layer provided on the negative electrode current collector. The negative electrode active material layer may include photoresist particles on a surface of the negative electrode active material layer. The negative electrode active material layer may include the negative pattern formed on an upper portion of the negative electrode active material layer.

### BRIEF DESCRIPTION OF DRAWINGS

FIG. 1 illustrates a simplified conceptual diagram showing a rechargeable lithium battery according to an example embodiment of the present disclosure.

FIG. 2 to FIG. 5 illustrating simplified diagrams showing a rechargeable lithium battery according to an example embodiment.

FIG. 6 is a cross-sectional view illustrating a rechargeable lithium battery according to example embodiments of the present disclosure.

FIG. 7 illustrates an enlarged cross-sectional view of the region M in FIG. 6.

FIG. 8 illustrates an enlarged plan view of the region M in FIG. 6.

FIG. 9 illustrates an enlarged plan view of the region A in FIG. 8.

FIG. 10 and FIG. 11 illustrate enlarged views of an example embodiment of a negative pattern that can be formed on the active material layer of the present disclosure.

FIG. 12, FIG. 13, and FIG. 14 illustrate cross-sectional views for describing a process of manufacturing a negative electrode according to an example embodiment of the present disclosure.

FIG. 15 illustrates a plan view of a negative electrode active material layer according to example embodiments of the present disclosure.

FIG. 16 is a flowchart illustrating a method of manufacturing a negative electrode for a rechargeable lithium battery, according to an example embodiment.

### DETAILED DESCRIPTION

To fully understand the configuration and effects of the present disclosure, some example embodiments are described with reference to the accompanying drawings. However, the present disclosure is not limited to the following example embodiments and may be implemented in various forms. The example embodiments are provided solely to illustrate the present disclosure and to enable those skilled in the art to fully understand its scope.

In this description, when an element is described as being “on” another element, it may be directly on the other element, or one or more intervening elements may be present. In the drawings, certain thicknesses may be exaggerated to better illustrate technical details. Throughout the specification, like reference numerals indicate like elements.

Unless explicitly stated otherwise, singular forms may also include plural forms. Furthermore, unless otherwise specified, the phrases “A or B,” “at least one of A and B,” “at least one of A or B,” “A, B, or C,” “at least one of A, B, and C,” and “at least one of A, B, or C” include any one or all possible combinations of the listed elements. The terms “comprises/includes” and “comprising/including” do not exclude the presence or addition of one or more other components.

In this description, the phrase “combination thereof” may refer to a mixture, a stack, a composite, a copolymer, an alloy, a blend, or a reaction product.

When the terms “about” or “substantially” are used in this specification in connection with a numerical value, it is intended that the associated numerical value include a tolerance of ±10% around the stated numerical value. When ranges are specified, the range includes all values therebetween such as increments of 0.1%.

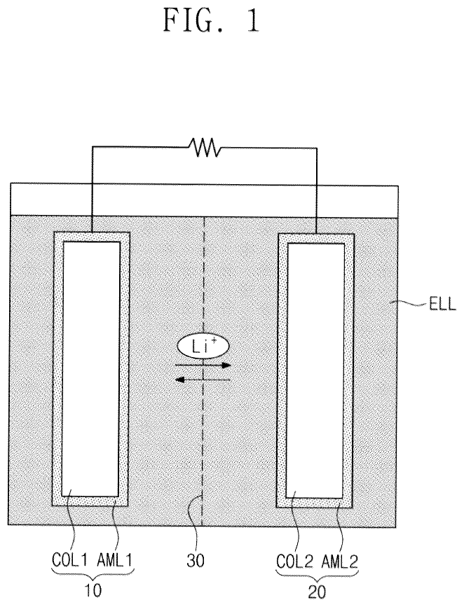

FIG. 1 illustrates a simplified conceptual diagram showing a rechargeable lithium battery according to an example embodiment of the present disclosure. Referring to FIG. 1, the rechargeable lithium battery may include a positive electrode 10, a negative electrode 20, a separator 30, and an electrolyte ELL.

The positive electrode 10 and the negative electrode 20 may be spaced apart from each other across the separator 30. The separator 30 may be disposed between the positive electrode 10 and the negative electrode 20. The positive electrode 10, the negative electrode 20, and the separator 30 may be in contact with the electrolyte ELL. The positive electrode 10, the negative electrode 20, and the separator 30 may be impregnated in the electrolyte ELL.

The electrolyte ELL may be or include a medium by which lithium ions are transferred between the positive electrode 10 and the negative electrode 20. In the electrolyte ELL, the lithium ions may move through the separator 30 toward one of the positive electrode 10 and the negative electrode 20.

### Positive Electrode 10

The positive electrode 10 for the rechargeable lithium battery may include a current collector COL1, and a positive electrode active material layer AML1 formed on the current collector COL1. The positive electrode active material layer AML1 may include a positive electrode active material, and may further include a binder and/or a conductive material.

For example, the positive electrode 10 may further include an additive that can constitute a sacrificial positive electrode.

An amount of the positive electrode active material may be in a range of about 90 wt % to about 99.5 wt % relative to 100 wt % of the positive electrode active material layer AML1. An amount of each of the binder and the conductive material may be in a range of about 0.5 wt % to about 5 wt % relative to 100 wt % of the positive electrode active material layer AML1.

The binder may improve attachment of positive electrode active material particles to each other, and may also improve attachment of the positive electrode active material to the current collector COL1. The binder may include, for example, at least one of polyvinyl alcohol, carboxymethyl cellulose, hydroxypropyl cellulose, diacetyl cellulose, polyvinylchloride, carboxylated polyvinylchloride, polyvinylfluoride, ethylene oxide-containing polymer, polyvinylpyrrolidone, polyurethane, polytetrafluoroethylene, polyvinylidene fluoride, polyethylene, polypropylene, styrene-butadiene rubber, (meth)acrylated styrene-butadiene rubber, epoxy resin, (meth)acrylic resin, polyester resin, or nylon, but the present disclosure is not limited thereto.

The conductive material may provide an electrode with conductivity, and any suitable conductive material that does not cause a chemical change in a battery may be used as the conductive material. The conductive material may include, for example, a carbon-based material such as at least one of natural graphite, artificial graphite, carbon black, acetylene black, Ketjen black, carbon fiber, carbon nano-fiber, and carbon nano-tube; a metal powder or metal fiber containing at least one or more of copper, nickel, aluminum, and silver; a conductive polymer such as a polyphenylene derivative; or a mixture thereof.

Aluminum (Al) may be used as the current collector COL1, but the present disclosure is not limited thereto.

### Positive Electrode Active Material

The positive electrode active material in the positive electrode active material layer AML1 may include a compound (e.g., lithiated intercalation compound) that can reversibly intercalate and deintercalate lithium. For example, the positive electrode active material may include at least one type of composite oxide including lithium and metal that is or includes at least one of cobalt, manganese, nickel, or a combination thereof.

The composite oxide may include lithium transition metal composite oxide, for example, at least one of lithium-nickel-based oxide, lithium-cobalt-based oxide, lithium-manganese-based oxide, lithium-iron-phosphate-based compounds, cobalt-free nickel-manganese-based oxide, or a combination thereof.

For example, the positive electrode active material may include a compound expressed by one of chemical formulae below. LiₐA_{1-b}X_{b}O_{2-c}D_{c} (where 0.90≤a≤1.8, 0≤b≤0.5, and 0≤c≤0.05); LiₐMn_{2-b}X_{b}O_{4-c}D_{c} (where 0.90≤a≤1.8, 0≤b≤0.5, and 0≤c≤0.05); LiₐNi_{1-b-c}Co_{b}X_{c}O_{2-α}D_{α} (where 0.90≤a≤1.8, 0≤b≤0.5, 0≤c≤0.5, and 0<α<2); LiₐNi_{1-b-c}Mn_{b}X_{c}O_{2-α}D_{α} (where 0.90<a≤1.8, 0<b≤0.5, 0<c<0.5, and 0<α<2); LiₐNi_{b}Co_{c}L¹_{d}GₑO₂ (where 0.90≤a≤1.8, 0≤b≤0.9, 0≤c≤0.5, 0≤d≤0.5, and 0≤e≤0.1); LiₐNiG_{b}O₂ (where 0.90≤a≤1.8 and 0.001≤b≤0.1); LiₐCoG_{b}O₂ (where 0.90≤a≤1.8 and 0.001≤b≤0.1); LiₐMn_{1-b}G_{b}O₂ (where 0.90≤a≤1.8 and 0.001≤b≤0.1); LiₐMn₂G_{b}O₄ (where 0.90≤a≤1.8 and 0.001≤b≤0.1); LiₐMn_{1-g}G_{g}PO₄ (where 0.90≤a≤1.8 and 0≤g≤0.5); Li_{(3-f)} Fe₂(PO₄)₃ (where 0≤f≤2); LiₐFePO₄ (where 0.90≤a≤1.8).

In the chemical formulae above, A may be or include at least one of Ni, Co, Mn, or a combination thereof, X may be or include at least one of Al, Ni, Co, Mn, Cr, Fe, Mg, Sr, V, a rare-earth element, or a combination thereof, D may be or include at least one of O, F, S, P, or a combination thereof, G may be or include at least one of Al, Cr, Mn, Fe, Mg, La, Ce, Sr, V, or a combination thereof, and L¹ may be or include at least one of Mn, Al, or a combination thereof.

For example, the positive electrode active material may be or include a high-nickel-based positive electrode active material having a nickel amount of equal to or greater than about 80 mol %, equal to or greater than about 85 mol %, equal to or greater than about 90 mol %, equal to or greater than about 91 mol %, or equal to or greater than about 94 mol % and equal to or less than about 99 mol % relative to 100 mol % of metal devoid of lithium in the lithium transition metal composite oxide. The high-nickel-based positive electrode active material may achieve high capacity, and may thus be applied to a high-capacity and high-density rechargeable lithium battery.

### Negative Electrode 20

The negative electrode 20 for the rechargeable lithium battery may include a current collector COL2 and a negative electrode active material layer AML2 positioned on the current collector COL2. The negative electrode active material layer AML2 may include a negative electrode active material, and may further include a binder and/or a conductive material.

For example, the negative electrode active material layer AML2 may include a negative electrode active material in a range of about 90 wt % to about 99 wt %, a binder in a range of about 0.5 wt % to about 5 wt %, and a conductive material in a range of about 0 wt % to about 5 wt %.

The binder may improve attachment of negative electrode active material particles to each other, and may also improve attachment of the negative electrode active material to the current collector COL2. The binder may include a non-aqueous binder, an aqueous binder, a dry binder, or a combination thereof.

The non-aqueous binder may include at least one of polyvinyl chloride, carboxylated polyvinyl chloride, polyvinyl fluoride, ethylene propylene copolymer, polystyrene, polyurethane, polytetrafluoroethylene, polyvinylidene fluoride, polyethylene, polypropylene, polyamide imide, polyimide, or a combination thereof.

The aqueous binder may include at least one of styrene-butadiene rubber, (meth)acrylated styrene-butadiene rubber, (meth)acrylonitrile-butadiene rubber, (meth)acrylic rubber, butyl rubber, fluoro elastomer, polyethylene oxide, polyvinyl pyrrolidone, polyepichlorohydrin, polyphosphazene, poly(meth)acrylonitrile, ethylene propylene diene copolymer, polyvinyl pyridine, chlorosulfonated polyethylene, latex, polyester resin, (meth)acrylic resin, phenolic resin, epoxy resin, polyvinyl alcohol, or a combination thereof.

When an aqueous binder is used as the negative electrode binder, a cellulose-based compound capable of providing viscosity may further be included. The cellulose-based compound may include one or more of carboxymethyl cellulose, hydroxypropylmethyl cellulose, methyl cellulose, or alkali metal salts thereof. The alkali metal may include at least one of Na, K, or Li.

The dry binder may include a fibrillizable polymer material, for example, at least one of polytetrafluoroethylene, polyvinylidene fluoride, polyvinylidene fluoride-hexafluoropropylene copolymer, polyethylene oxide, or a combination thereof.

The conductive material may provide an electrode with conductivity, and any suitable conductive material that does not cause a chemical change in a battery may be used as the conductive material. For example, the conductive material may include a carbon-based material such as at least one of natural graphite, artificial graphite, carbon black, acetylene black, Ketjen black, carbon fiber, carbon nano-fiber, and carbon nano-tube; a metal powder or metal fiber including at least one or more of copper, nickel, aluminum, and silver; a conductive polymer such as a polyphenylene derivative; or a mixture thereof.

The current collector COL2 may include at least one of a copper foil, a nickel foil, a stainless-steel foil, a titanium foil, a nickel foam, a copper foam, a polymer substrate coated with a conductive metal, or a combination thereof.

### Negative Electrode Active Material

The negative electrode active material in the negative electrode active material layer AML2 may include at least one of a material that can reversibly intercalate and deintercalate lithium ions, lithium metal, a lithium metal alloy, a material that can be doped and de-doped with lithium, or transition metal oxide.

The material that can reversibly intercalate and deintercalate lithium ions may include a carbon-based negative electrode active material, for example, crystalline carbon, amorphous carbon, or a combination thereof. For example, the crystalline carbon may include graphite such as non-shaped, sheet-shaped, flake-shaped, sphere-shaped, or fiber-shaped natural or artificial graphite, and the amorphous carbon may include at least one of soft carbon, hard carbon, mesophase pitch carbon, or calcined coke.

The lithium metal alloy may include an alloy of lithium and metal that is or includes at least one of Na, K, Rb, Cs, Fr, Be, Mg, Ca, Sr, Si, Sb, Pb, In, Zn, Ba, Ra, Ge, Al, and Sn.

The material that can be doped and de-doped with lithium may include a Si-based negative electrode active material or a Sn-based negative electrode active material. The Si-based negative electrode active material may include at least one of silicon, silicon-carbon composite, SiOₓ (where 0<x≤2), Si-Q alloy (where Q is or includes at least one of alkali metal, alkaline earth metal, Group 13 element, Group 14 element (except for Si), Group 15 element, Group 16 element, transition metal, a rare-earth element, or a combination thereof), or a combination thereof. The Sn-based negative electrode active material may include at least one of Sn, SnO₂, a Sn-based alloy, or a combination thereof.

The silicon-carbon composite may be or include a composite of silicon and amorphous carbon. According to an example embodiment, the silicon-carbon composite may have a structure in which the amorphous carbon is coated on a surface of the silicon particle. For example, the silicon-carbon composite may include a secondary particle (core) in which primary silicon particles are assembled, and an amorphous carbon coating layer (shell) positioned on a surface of the secondary particle. The amorphous carbon may also be positioned between the primary silicon particles, and for example, the primary silicon particles may be coated with the amorphous carbon. The secondary particles may be dispersed in an amorphous carbon matrix.

The silicon-carbon composite may further include crystalline carbon. For example, the silicon-carbon composite may include a core including crystalline carbon and silicon particles, and may also include an amorphous carbon coating layer positioned on a surface of the core.

The Si-based negative electrode active material or the Sn-based negative electrode active material may be used in combination with a carbon-based negative electrode active material.

### Separator 30

Based on a type of the rechargeable lithium battery, the separator 30 may be present between positive electrode 10 and the negative electrode 20. The separator 30 may include at least one or more of polyethylene, polypropylene, and polyvinylidene fluoride, and may have a multi-layered separator thereof such as a polyethylene/polypropylene bi-layered separator, a polyethylene/polypropylene/polyethylene tri-layered separator, and a polypropylene/polyethylene/polypropylene tri-layered separator.

The separator 30 may include a porous substrate and a coating layer positioned on one surface, or on opposite surfaces, of the porous substrate, the coating layer including an organic material, an inorganic material, or a combination thereof.

The porous substrate may be or include a polymer layer including at least one of polyolefin such as polyethylene and polypropylene, polyester such as polyethylene terephthalate and polybutylene terephthalate, polyacetal, polyamide, polyimide, polycarbonate, polyetherketone, polyaryletherketone, polyetherimide, polyamideimide, polybenzimidazole, polyethersulfone, polyphenyleneoxide, cyclic olefin copolymer, polyphenylenesulphide, polyethylene naphthalate, glass fiber, Teflon, and polytetrafluoroethylene, or may be or include a copolymer or mixture including two or more of the materials mentioned above.

The organic material may include a polyvinylidenefluoride-based copolymer or a (meth)acrylic copolymer.

The inorganic material may include an inorganic particle such as at least one of Al₂O₃, SiO₂, TiO₂, SnO₂, CeO₂, MgO, NiO, CaO, GaO, ZnO, ZrO₂, Y₂O₃, SrTiO₃, BaTiO₃, Mg(OH)₂, Boehmite, or a combination thereof, but the present disclosure is not limited thereto.

The organic material and the inorganic material may be mixed in one coating layer, or may be present as a stack of a coating layer including the organic material and a coating layer including an inorganic material.

### Electrolyte ELL

The electrolyte ELL for the rechargeable lithium battery may include a non-aqueous organic solvent and a lithium salt.

The non-aqueous organic solvent may constitute a medium for transmitting ions that participate in an electrochemical reaction of the battery.

The non-aqueous organic solvent may include at least one of a carbonate-based solvent, an ester-based solvent, an ether-based solvent, a ketone-based solvent, an alcohol-based solvent, an aprotic solvent, or a combination thereof.

The carbonate-based solvent may include at least one of dimethyl carbonate (DMC), diethyl carbonate (DEC), dipropyl carbonate (DPC), methylpropyl carbonate (MPC), ethylpropyl carbonate (EPC), methylethyl carbonate (MEC), ethylene carbonate (EC), propylene carbonate (PC), or butylene carbonate (BC).

The ester-based solvent may include at least one of methyl acetate, ethyl acetate, n-propyl acetate, dimethyl acetate, methyl propionate, ethyl propionate, decanolide, mevalonolactone, valerolactone, or caprolactone.

The ether-based solvent may include at least one of dibutyl ether, tetraglyme, diglyme, dimethoxyethane, 2-methyltetrahydrofuran, 2.5-dimethyltetrahydrofuran, or tetrahydrofuran. The ketone-based solvent may include cyclohexanone. The alcohol-based solvent may include ethyl alcohol or isopropyl alcohol. The aprotic solvent may include at least one of nitriles such as R—CN (where R is a hydrocarbon group having a C2 to C20 linear, branched, or cyclic structure and may include a double bond, an aromatic ring, or an ether group); amides such as dimethylformamide; dioxolanes such as 1,3-dioxolane or 1.4-dioxolane; or sulfolanes.

The non-aqueous organic solvent may be used alone, or in a mixture of two or more solvents.

In addition, when a carbonate-based solvent is used, a cyclic carbonate and a chain carbonate may be mixed, and the cyclic carbonate and the chain carbonate may be mixed in a volume ratio in a range of about 1:1 to about 1:9.

The lithium salt may be or include a material that dissolves in the non-aqueous organic solvent to constitute a supply source of lithium ions in the battery, and enables an operation of the rechargeable lithium battery and promotes the movement of lithium ions between positive and negative electrodes. The lithium salt may include, for example, at least one of LiPF₆, LiBF₄, LiSbF₆, LiAsF₆, LiClO₄, LiAlO₂, LiAlCl₄, LiPO₂F₂, LiCl, LiI, LiN(SO₃C₂F₅)₂, Li(FSO₂)₂N (lithium bis(fluorosulfonyl)imide, LiFSI), LiC₄F₉SO₃, LiN(CₓF₂ₓ₊₁SO₂)(C_{y}F_{2y+1}SO₂) (where x and y are integers of 1 to 20), lithium trifluoromethane sulfonate, lithium tetrafluoroethanesulfonate, lithium difluoro (oxalato) borate (LiDFOB), lithium difluorobis(oxalato)phosphate (LiDFOP), or lithium bis(oxalato) borate (LiBOB).

### Rechargeable Lithium Battery

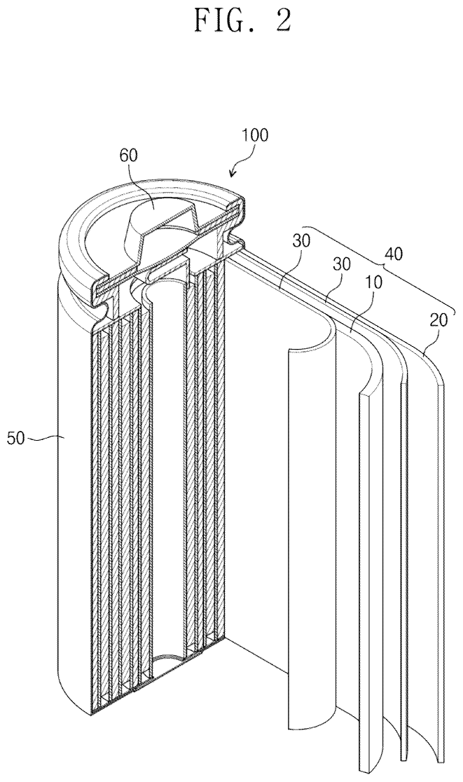

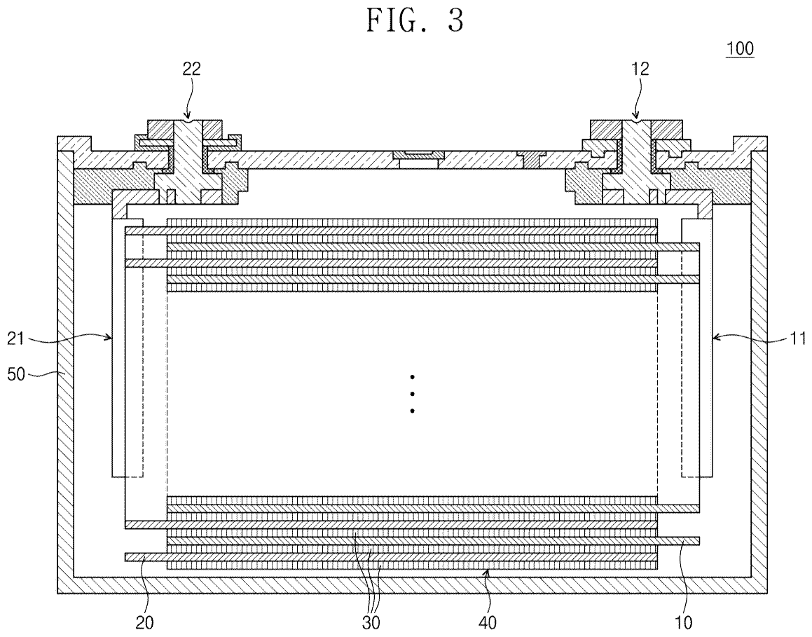

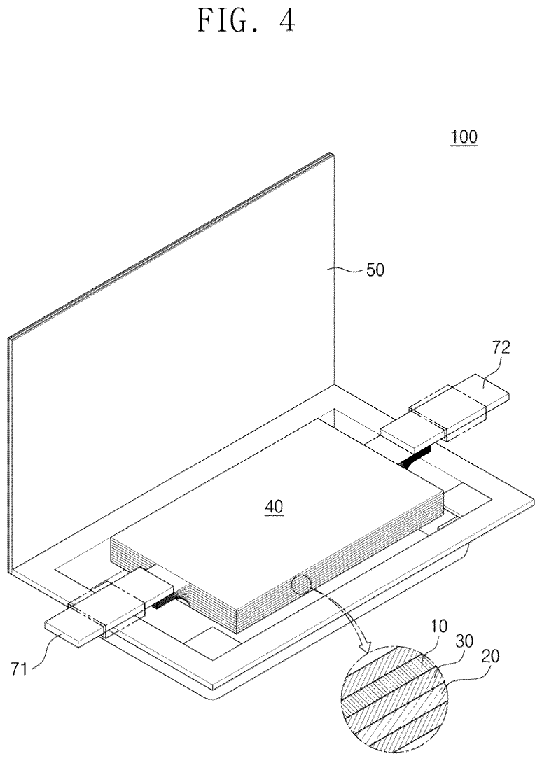

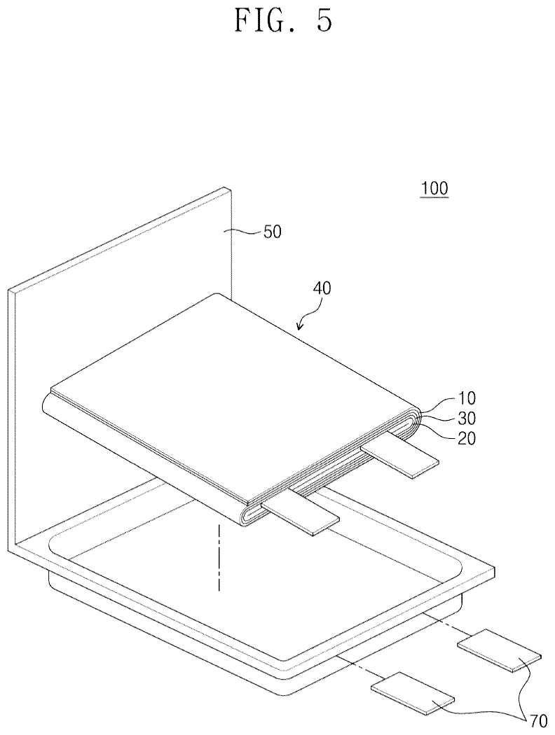

Based on a shape of the rechargeable lithium battery, the rechargeable lithium battery may be classified into cylindrical, prismatic, pouch, and coin types. In FIG. 2 to FIG. 5 illustrating simplified diagrams showing the rechargeable lithium battery according to an example embodiment, FIG. 2 shows a cylindrical battery, FIG. 3 shows a prismatic battery, and FIG. 4 and FIG. 5 show pouch-type batteries. Referring to FIG. 2 to FIG. 4, the rechargeable lithium battery 100 may include an electrode assembly 40 in which a separator 30 is interposed between a positive electrode 10 and a negative electrode 20, and may also include a casing 50 in which the electrode assembly 40 is accommodated. The positive electrode 10, the negative electrode 20, and the separator 30 may be impregnated in an electrolyte (not shown). The rechargeable lithium battery 100 may include a sealing member 60 that seals the casing 50 as illustrated in FIG. 2. In addition, as illustrated in FIG. 3, the rechargeable lithium battery 100 may include a positive electrode lead tab 11, a positive electrode terminal 12 connected to the positive electrode lead tab 11, a negative electrode lead tab 21, and a negative electrode terminal 22 connected to the negative electrode lead tab 21. As shown in FIG. 4 and FIG. 5, the rechargeable lithium battery 100 may include an electrode tab 70 illustrated in FIG. 5, or a positive electrode tab 71 and a negative electrode tab 72 illustrated in FIG. 4, the electrode tabs 70/71/72 forming an electrical path for externally inducing a current generated in the electrode assembly 40.

Hereinafter, a rechargeable lithium battery according to example embodiments of the present disclosure is described in more detail.

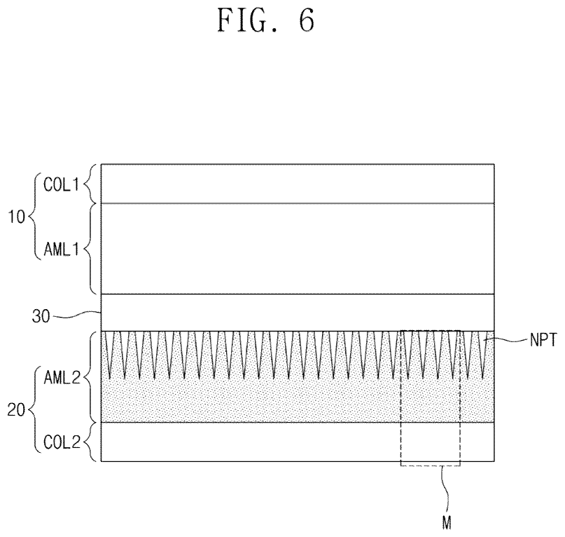

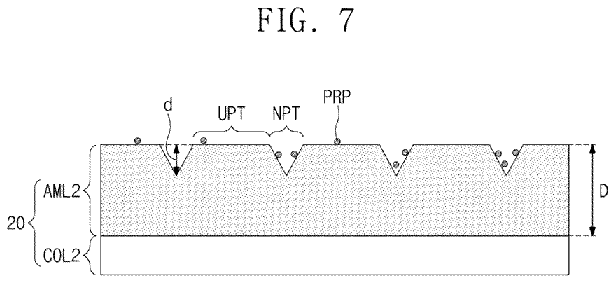

FIG. 6 is a cross-sectional view illustrating the rechargeable lithium battery according to example embodiments of the present disclosure. FIG. 7 illustrates an enlarged cross-sectional view of the region “M” of FIG. 6.

Referring to FIG. 6, as described above with reference to FIG. 1, the rechargeable lithium battery according to the present disclosure may include a positive electrode 10, a negative electrode 20, and a separator 30 between the positive electrode 10 and the negative electrode 20. Although not explicitly shown in FIG. 6, the rechargeable lithium battery according to the present disclosure may further include an electrolyte ELL. The separator 30 may be impregnated with the electrolyte ELL.

The positive electrode 10 may include a positive electrode current collector COL1, and a positive electrode active material layer AML1 on the positive electrode current collector COL1. The negative electrode 20 may include a negative electrode current collector COL2, and a negative electrode active material layer AML2 on the negative electrode current collector COL2. The separator 30 may be interposed between the positive electrode active material layer AML1 and the negative electrode active material layer AML2.

Referring to FIG. 7, the negative electrode active material layer AML2 may include a plurality of negative patterns NPT formed thereon. Each of, or at least one of, the plurality of negative patterns NPT may extend from the upper surface of the negative electrode active material layer AML2 toward the lower surface of the negative electrode active material layer AML2. The upper surface of the negative electrode active material layer AML2 may be adjacent to, or in contact with, the separator 30. In other words, the plurality of negative patterns NPT may be adjacent to the separator 30. The electrolyte ELL may fill a space in a plurality of the negative patterns NPT.

The negative electrode active material layer AML2 may include a plurality of photoresist particles PRP formed thereon. Each of, or at least one of, the plurality of photoresist particles PRP may be provided on the surface of the negative pattern NPT and the surface of the non-negative pattern UPT.

According to an example embodiment of the present disclosure, each of, or at least one of, the photoresist particles PRP may include a photoresist resin and a photo-acid generator, details of which are described below in the photoresist composition.

Referring again to FIG. 7, the maximum depth (d) of the negative pattern NPT may be less than the thickness (D) of the negative electrode active material layer AML2. For example, a ratio (d/D) of the maximum depth (d) of the negative pattern NPT to the thickness (D) of the negative electrode active material layer AML2 may be greater than 0 and less than or equal to about 0.1.

Referring again to FIG. 7, the amount of photoresist particles PRP located on the surface of the negative pattern NPT may be greater than the amount of photoresist particles PRP located on the surface the non-negative pattern UPT. This may be confirmed through SEM cross-sectional analysis, and for example, can be confirmed by sampling a region (1 cm²) having a width of 1 cm and a height of 1 cm in the negative electrode active material layer AML2.

In an example embodiment, the density of the photoresist particles PRP of the negative pattern NPT may be greater than the density of the photoresist particles PRP of the non-negative pattern UPT. In the present disclosure, the “density of photoresist particles” may be defined as a ratio of an area occupied by the photoresist particle PRP within a unit area (e.g., 10,000 μm², 100 μm in width×100 μm in height) of the negative electrode active material layer AML2 in a cross-sectional image of the negative electrode activity material layer AML2, as illustrated in FIG. 7.

For example, the prepared 1 cm² sample is fixed to an SEM stage, and then an SEM is taken to obtain a cross-sectional image. After the image is retrieved using an image analysis tool (e.g., MATLAB, ImageJ, and the like), a binary thresholding process may be performed to separate the photoresist particles PRP and the negative electrode active material layer AML2 based on contrast. An image separated through binarization is converted into a black region which is a negative electrode active material layer region and a white region which is a photoresist particle region through appropriate threshold setting, and then the density of the photoresist particles may be obtained through the following Equation 1.

$$Density of photoresist particles ( \% ) = ( Number of white region pixels / Total number of pixels ) \times 100. \qquad Equation 1$$

When the density of the photoresist particles of the negative pattern NPT is greater than the density of the photoresist particles of the non-negative pattern UPT, the imbalance of the migration resistance of lithium ions that may occur between the negative pattern NPT and the non-negative pattern UPT can be improved, so that the rechargeable lithium battery can be driven more stably. In addition, the presence of the photoresist particles PPR in the negative pattern NPT can enhance the mechanical strength of the negative electrode 20 to reduce or prevent damage to the negative electrode 20.

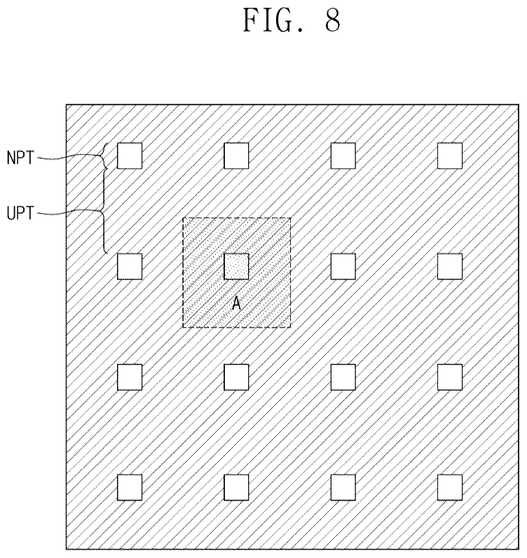

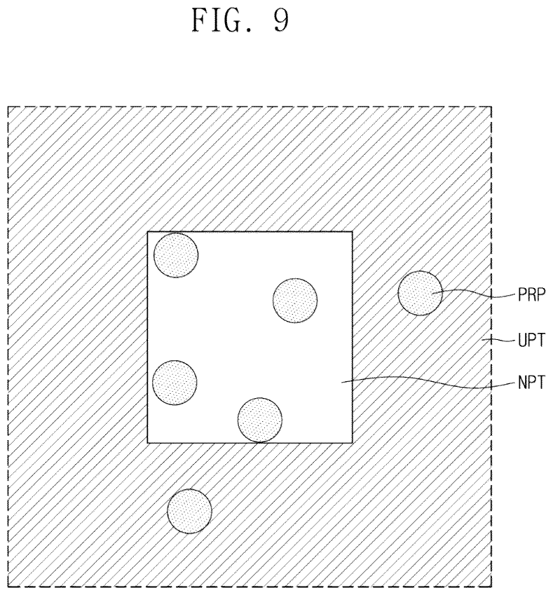

FIG. 8 illustrates a plan view of the region “M” of FIG. 6 as viewed in the horizontal direction. FIG. 9 illustrates an enlarged plan view of the region “A” of FIG. 8.

Referring to FIG. 8 and FIG. 9, the “unit area A” herein may be defined as an area of 1 cm in width and 1 cm in height (1 cm²) in the negative electrode active material layer AML2, and the “area density of photoresist particles” may be defined as the area of the photoresist particle PRP in the unit area “A.” Accordingly, the area density of the photoresist particles on the surface of the negative electrode active material layer AML may be greater than 0 and less than or equal to about 0.05 cm².

For example, a sample of the prepared unit region “A” is photographed with an optical microscope to observe regions where the photoresist particles PRP are present in the surface of the negative electrode active material layer AML2. The regions where the photoresist particles PRP are present are each photographed with an SEM to obtain images. After the images are retrieved using an image analysis tool (e.g., MATLAB, ImageJ, and the like), a binary thresholding process may be performed to separate the photoresist particles PRP and the negative electrode active material layer AML2 based on contrast. Images separated by binarization are converted into a black region which is a negative electrode active material layer region, and a white region which is a photoresist particle region by setting appropriate thresholds, and then the area density of the photoresist particles may be obtained by calculating the sum of the areas occupied by the white regions in each image.

When the area density of the photoresist particles is greater than 0 and less than or equal to about 0.05 cm², the rechargeable lithium battery may be stably driven by hindering or preventing the electrode plate from falling off during the negative patterning process and charging/discharging, without disturbing the movement of the lithium ions on the surface of the negative electrode. On the other hand, when the area density of the photoresist particles exceeds about 0.05 cm², lithium migration on the surface of the negative electrode may be hindered to increase the lithium ions migration resistance, and the rate-limiting characteristics of the rechargeable lithium battery may be deteriorated.

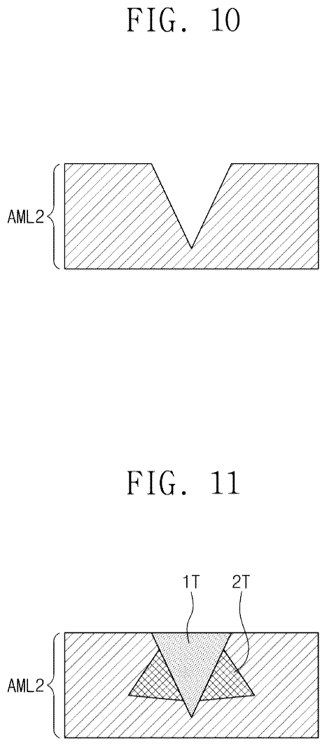

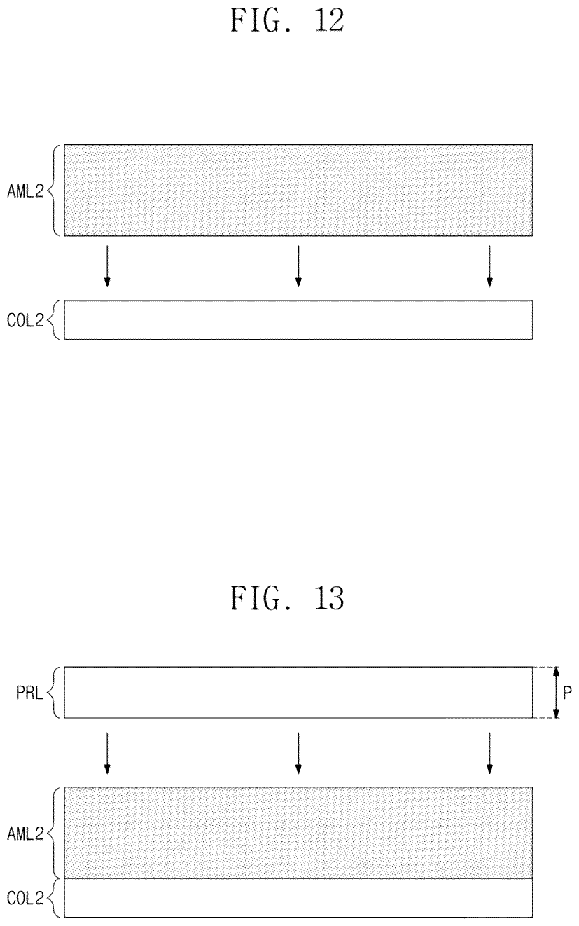

FIG. 10 illustrates an enlarged view relating to a triangular shape, which is one example embodiment of a negative pattern that can be formed on the negative electrode active material layer AML2 of the present disclosure. FIG. 11 illustrates an enlarged view of a multi-hole shape, which is another example embodiment of a negative pattern that can be formed on the negative electrode active material layer AML2 of the present disclosure.

Referring to FIG. 11, the multi-hole shape herein may not be a simple shape such as a triangular shape, but may be a polyhedral shape composed of or include various polygons. In one example embodiment, the multi-hole shape may be a fractal shape with self-similarity in which the entire structure and some structures repeatedly exhibit the same or similar pattern.

In an example, the multi-hole shape may include a first triangular shape 1T and a second triangular shape 2T on one side of the first triangular image 1T. The size of the second triangular shape 2T may be smaller than the size of the first triangular shape 1T. By forming the multi-hole shape, the migration resistance of lithium ions at the negative electrode active material layer AML2 interface can be reduced and ion conductivity can be improved.

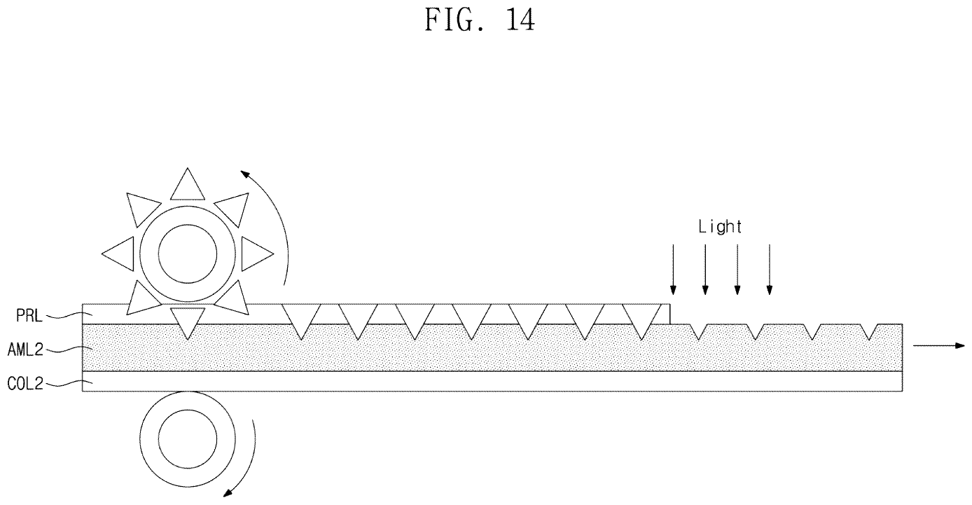

FIG. 12 and FIG. 13 illustrate cross-sectional views for explaining a process of manufacturing a negative electrode according to an example embodiment of the present disclosure.

Referring to FIG. 12 and FIG. 13, the negative electrode active material layer AML2 may be formed on the negative electrode current collector COL2. In addition, the photoresist layer PRL may be formed on the negative electrode active material layer AML2. For example, forming the negative electrode active material layer AML2 and the photoresist layer PRL may be performed by a coating method. By forming the photoresist layer PRL on the negative electrode active material layer AML2, the photoresists layer PRL may constitute a protective layer that reduces or suppresses falling off of the negative electrode active materials and reduces or minimizes damage to the negative electrode during the negative patterning step.

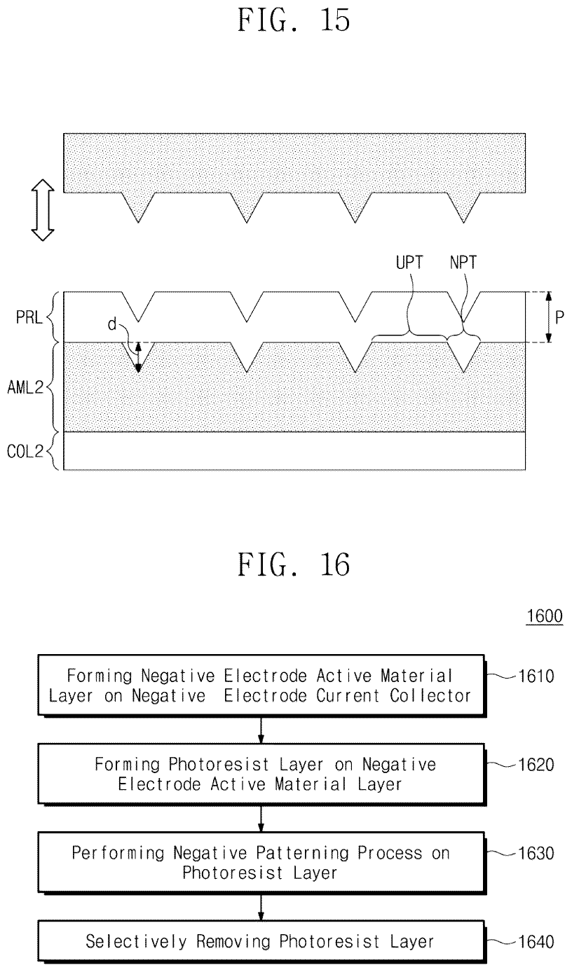

FIG. 14 illustrates a conceptual diagram for explaining a method for manufacturing an electrode for the rechargeable lithium battery including a process of forming a negative pattern NPT on the negative electrode active material layer AML2 according to an example embodiment of the present disclosure. FIG. 15 illustrates a cross-sectional view for explaining a method for manufacturing an electrode for the rechargeable lithium battery including a process of forming a negative pattern NPT on the negative electrode active material layer AML2 by a roll press method according to an example embodiment of the present disclosure.

Referring to FIG. 14 and FIG. 15, a negative patterning process may be performed on the negative electrode active material layer AML2. A plurality of negative patterns NPT may be formed over the photoresist layer PRL and the negative electrode active material layer AML2. In one example embodiment, the negative pattern process may be performed by a press in which a plurality of positive patterns are formed. For example, the negative patterning process may be performed by a roll press method. For example, the upper roll may be formed with a positive pattern. For example, the lower roll may not have a positive pattern formed.

Referring to FIG. 15, the thickness (P) of the photoresist layer PRL may be formed such that the ratio (d/P) of the maximum depth (d) of the negative pattern to the thickness (P) of a photoresist layer PRL is greater than 0 and less than or equal to about 1. When the ratio (d/P) is greater than 0 and less than or equal to about 1, the photoresists layer PRL can play a role of a protective layer that reduces or suppresses falling off of the negative electrode active material during the progress of the negative patterning step. When the ratio (d/P) exceeds 1, the positive pattern of the press comes into direct contact with the negative electrode active material layer AML2 during pressurization, which may lead to detachment of the active material and damage to the negative electrode.

Referring to FIG. 14, the photoresist layer PRL on which the negative pattern NPT is formed may be selectively removed through an exposure process. The exposure process may set the wavelength of the light to be irradiated differently depending on the type of the photoresist composition.

Referring to FIG. 13 and FIG. 14, the photoresist composition according to example embodiments of the present disclosure may be or include a chemically amplified resist type photoresist composition.

The photoresist composition of the present disclosure may include at least one of a photoresist resin, a photo-acid generator (PAG), an additive, and a solvent.

As an example, the photoresist resin may include a polymer represented by the following formula 1A.

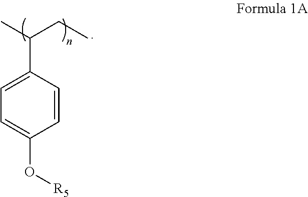

In Formula 1A, R₆ may be hydrogen or an alkyl group having about 1 to about 15 carbon atoms. n may be an integer in a range of about 10 and about 1,000,000.

As another example embodiment, the photoresist resin may include a polymer represented by the following formula 1B.

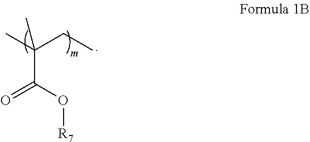

In Formula 1B, R₇ may be hydrogen or an alkyl group having about 1 to about 15 carbon atoms. m may be an integer in a range of about 10 and about 1,000,000.

In another example embodiment, the photoresist resin may include a block copolymer represented by the following formula 1C.

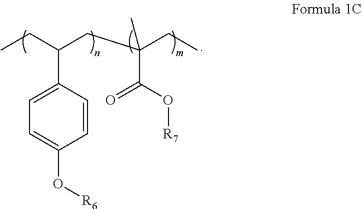

In Formula 1C, R₆ and R₇ may each independently be hydrogen or an alkyl group having about 1 to about 15 carbon atoms. Each of n and m may be an integer in a range of about 10 and about 1,000,000.

The photoresist resin according to an example embodiment of the present disclosure may include a block copolymer represented by the following formula 1D.

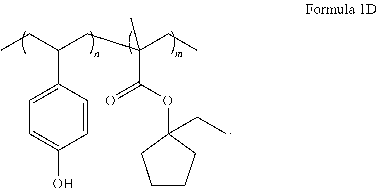

In Formula 1D, each of n and m may be an integer in a range of about 10 and about 1,000,000.

The photo-acid generator may include a substance capable of generating an acid by receiving light of a specific wavelength.

The solvent may include at least one of ethyl cellosolve acetate (ECA), ethyl lactate (EL), propylene glycol monomethyl ether acetate (PGMEA), propylene glycol methyl ether (PGME), N-butyl acetate (n-BA), 2-heptanone (MAK), methyl ethyl ketone (MEK), N,N-Dimethyl formamide (DMF), N-Methylpyrrolidone (NMP), ethyl 3-ethoxypropionate (EEP), methyl 3-methoxypropionate, ethyl pyruvate (EP), and isopropyl alcohol (IPA).

As the photo-resist composition, those used in a general semiconductor process can be used without limitation, and those described above are merely examples and are not particularly limited thereto.

A slitting process and a notching process may be performed, e.g., sequentially performed, on the negative electrode 20 after performing the negative patterning process. The rechargeable lithium battery according to examples of the present disclosure may be produced by stacking the negative electrode 20, the separator 30, and the positive electrode 10, and providing the electrolyte ELL.

FIG. 16 is a flowchart illustrating a method of manufacturing a negative electrode for a rechargeable lithium battery, according to an example embodiment. In FIG. 16, the method 1600 includes operation 1610, which includes forming a negative electrode active material layer on a negative electrode current collector. Operation 1620 includes forming a photoresist layer on the negative electrode active material layer. For example, the forming the photoresist layer includes coating a photoresist composition, and wherein the photoresist composition includes at least one of a photoresist resin, a photo-acid generator, a quencher, an additive, and a solvent. Operation 1630 includes performing a negative patterning process on the photoresist layer to form a negative pattern on the negative electrode active material layer. For example, forming the negative pattern comprises performing roll pressing. In another example, a ratio (d/P) of a maximum depth (d) of the negative pattern to a thickness (P) of the photoresist layer is greater than 0 and less than or equal to about 1. In a further example, the negative pattern has a triangular shape. In yet another example, the negative pattern has a multi-hole shape. In a further example, the multi-hole shape includes a first triangular shape, and a second triangular shape on one side of the first triangular shape, wherein a size of the second triangular shape is smaller than a size of the first triangular shape. Operation 1640 includes selectively removing the photoresist layer.

Hereinafter, Embodiments and Comparative Examples of the present disclosure are described. However, the following embodiments are merely examples of the present disclosure, and the present disclosure is not limited to the following embodiments.

### Example 1

### Manufacturing of Negative Electrode:

Cu Foil having a thickness of 10 μm was prepared as a negative electrode current collector. Artificial graphite, a styrene-butadiene rubber binder, and carboxymethyl cellulose were mixed at a weight ratio of 98:1:1, and dispersed in distilled water to prepare a negative electrode active material slurry. The negative electrode active material slurry was coated on a current collector having a thickness of 10 μm, and dried at 100° C. to form a negative electrode active material layer.

A chemically amplified positive photoresist composition in which a photoresist resin (poly(hydroxystyrene)), a photo-acid generator (Triphenylsulfonium triflate), a solvent (PGMEA), and an additive (surfactant) were mixed was coated on the negative electrode active material layer to form a photoresist layer.

A roll press was performed on the photoresist layer using a roll on which triangular positive patterns were formed. Thus, a plurality of triangular negative patterns were formed on the negative electrode active material layer. For example, the negative pattern was formed such that the ratio (d/D) of the maximum depth (d) of the negative pattern to the thickness (D) of the negative electrode active material layer was equal to 0.1. The negative pattern was formed such that the ratio (d/P) of the maximum depth (d) of the negative pattern to the thickness (P) of the photoresist layer was equal to 1.

An exposure process was performed on the entire surface of the remaining photoresist layer to remove the photoresist layer. Thus, the negative electrode according to Example 1 was produced.

### Manufacturing of Rechargeable Lithium Battery:

Al Foil having a thickness of 15 μm was prepared as a positive electrode current collector. NCA (LiNiCoAlO₂) as a positive electrode active material, polyvinylidene fluoride as a binder, and acetylene black as a conductive material were mixed at a weight ratio of 96:3:1. This mixture was then dispersed in N-methylpyrrolidone to prepare a positive electrode active material slurry.

The positive electrode active material slurry was coated on a current collector having a thickness of 15 μm, dried at 100° C., and then pressed to manufacture a positive electrode.

The positive electrode, the negative electrode, and a separator made of polyethylene with a thickness of 10 μm were assembled to prepare an electrode assembly, and the electrolyte was injected to prepare a rechargeable lithium battery.

### Example 2

In the negative patterning process, the positive pattern of the upper roll included the first triangular shape, and the second triangular shape on one side of the first triangular shape. The positive pattern has a fractal shape in which the size of the second triangular shape is smaller than the shape of the first triangular shape. A roll press process was performed with the top roll to form a negative pattern having a multi-hole shape. The rechargeable lithium battery was manufactured in the same manner as in Example 1, with the above difference.

### Comparative Example 1

The rechargeable lithium battery was manufactured in the same manner as in Example 1, with a difference that no photoresist layer was formed and the upper roll without a positive pattern was used for pressurization so that no negative pattern was formed on the negative electrode active material layer.

### Comparative Example 2

The rechargeable lithium battery was manufactured in the same manner as in Example 1, with a difference that no photoresist layer was formed.

### Evaluation Example 1: Evaluation of Active Material Loss Ratio after Pressing Step

The loss ratio of the active material was evaluated by comparing the measured Loading Level with the designed Loading Level after performing the negative patterning and the pressing process according to Examples 1 and 2 and Comparative Examples 1 and 2. Ten samples were measured for each of Examples and Comparative Examples, and the average value thereof was defined as Loading Level (measurement) and is shown in Table 1 below.

TABLE 1

| | | | Active | Active |
|---|---|---|---|---|
| | Loading | | Material | Material |
| | Level | Loading Level | Loss | Loss |
| | (Design) | (measurement) | Amount | Ratio |
| Distinction | (mg/cm²) | (mg/cm²) | (mg/cm²) | (%) |
| Example 1 | 15.00 | 14.77 | 0.23 | 1.5 |
| Example 2 | 15.00 | 14.60 | 0.40 | 2.7 |
| Comparative | 15.00 | 14.97 | 0.03 | 0.2 |
| Example 1 | | | | |
| Comparative | 15.00 | 14.10 | 0.90 | 6.0 |
| Example 2 | | | | |

Referring to Table 1, in Comparative Example 1 in which the negative pattern was not formed, the active material loss ratio was significantly lower than the active material loss ratio in Examples 1 to 2 and Comparative Example 2 in which the negative patterns were formed. In addition, in the case of Example 2 in which the fractal-shaped negative pattern was formed, the active material loss ratio was higher than the active material loss ratio in Example 1 in which the triangular-shaped engrafted pattern was formed. In Examples 1 and 2, where a triangular-shaped negative pattern is formed, the active material loss ratio is significantly lower when compared to Comparative Example 2, where the photoresist layer is not formed.

As a result, it can be confirmed that the more complex the negative pattern, the higher the active material loss ratio. However, the presence of the photoresist layer during the negative patterning step significantly reduce this loss.

### Evaluation Example 2: Evaluation of Lithium Ion Transfer Resistance

The rechargeable lithium batteries produced by Examples and Comparative Examples were discharged at 1 C in a buffered state (100% SOC). The 1 C discharge means that the battery capacity is discharged within one hour, and for example, a battery having a capacity of 2 Ah refers to a state in which the battery is discharged at a current of 2 A for one hour.

Frequencies ranging from 10 mHz to 1 Hz were set using electrochemical impedance spectroscopy (EIS) equipment and impedance was measured and visualized in Nyquist Plot form. The actual impedance value at which the formed semicircle meets the X axis on the Nyquist plot was extracted to measure the migration resistance of lithium ions, which is shown in Table 2 below.

### Evaluation Example 3: Capacity Retention Rate Evaluation

The rechargeable lithium batteries produced by Examples and Comparative Examples were charged to a buffered state (100% SOC), and discharging and charging at a constant current of 1 C were repeated 100 cycles to evaluate the capacity retention rate by the following Equation 2. A lower capacity retention means that the electrode interface structure is unstable and mechanical damage of the electrode has occurred. The evaluation results are shown in Table 2 below.

$$Capacity Retention Rate ( \% ) = ( Discharged Capacity / Initial Capacity ) \times 100. \qquad Equation 2$$

### Evaluation Example 4: Evaluation of Initial Charge-Discharge Efficiency

The rechargeable lithium secondary batteries produced by the Examples and comparative examples were evaluated for the First Coulombic Efficiency (FCE) by the following charge-discharge test. The charge-discharge test used a CC-CV mode, charging was performed at a constant current of 1 C until the battery voltage reached 4.2 V in a fully discharged state, and when 4.2 V was reached, the first charging was performed at 4.25 V at a constant voltage with a 0.05 C cut-off condition. Then, the first charge-discharge cycle was completed by performing the first discharge at a constant current of 0.1 C until the battery voltage reached 2.75 V. The initial charge-discharge efficiency was then measured by the following Equation 3, and the results are shown in the following Table 2. The higher the initial charge-discharge efficiency, the better the electrode structure and the interface stability of the electrode.

$$Initial Charge - Discharge Efficiency ( \% ) = ( discharge capacity of first charge - discharge cycle / charge capacity of first charge - discharging cycle ) \times 100. \qquad Equation 3$$

TABLE 2

| | | | Initial |
|---|---|---|---|
| | Li⁺ | Capacity | Charge- |
| | migration | Retention | Discharge |
| | resistance | Rate | Efficiency |
| Distinction | (Ω · cm²) | (%) | (%) |
| Example 1 | 15.52 | 89.8 | 91.9 |
| Example 2 | 12.74 | 88.7 | 90.7 |
| Comparative | 21.13 | 92.2 | 94.1 |
| Example 1 | | | |
| Comparative | 14.12 | 82.1 | 86.6 |
| Example 2 | | | |

Referring to Table 2, in Examples 1 and 2, in which the negative pattern was formed, the migration resistance of lithium ions was lower than the migration resistance of lithium ions in Comparative Example 1, in which no negative pattern was formed. It The migration resistance of lithium ions in Example 2, in which a fractal-shaped negative pattern was formed, was lower than the migration resistance of lithium ions in Example 1 and Comparative Example 2, in which a triangular-shaped negative pattern was formed. Accordingly, the migration resistance of lithium ions decreases with increasing complexity of the negative pattern.

Referring back to Table 2, Examples 1 and 2, in which the negative patterning process was performed with a photoresist layer formed, exhibited higher capacity retention and initial charge-discharge efficiency compared to Comparative Example 2, in which the negative patterning process was performed without forming a photoresist layer. Furthermore, Example 2, with a fractal-shaped negative pattern, showed lower capacity retention and initial charge-discharge efficiency than Example 1, with a triangular-shaped negative pattern. These results indicate that the capacity retention and the initial charge-discharge efficiency increase with greater structural stability of the negative electrode surface (e.g., when the active material loss ratio is lower).

The rechargeable lithium batteries according to the Examples were found to exhibit relatively lower lithium-ion migration resistance, while simultaneously or contemporaneously achieving relatively higher capacity retention and initial charge-discharge efficiency compared to the Comparative Examples.

The negative electrode according to the present disclosure may include a negative electrode active material layer in which a negative pattern is formed, whereby the migration resistance of lithium ions can be reduced. In addition, when the negative patterning process is performed after the photoresist layer is formed, detachment of the negative electrode active material can be reduced or suppressed. As a result, the rechargeable lithium battery according to the present disclosure can have safety and desired or improved capacity.

While the present disclosure has been described with reference to example embodiments, it should be understood that these example embodiments are provided for illustrative purposes only and do not limit the scope of the present disclosure. Various modifications and equivalent arrangements may be made without departing from the spirit and scope of the appended claims. Accordingly, the described embodiments should be regarded as examples rather than limitations of the present disclosure.

What is claimed is:

1. A method for manufacturing a negative electrode for a rechargeable lithium battery, the method comprising:
forming a negative electrode active material layer on a negative electrode current collector;
forming a photoresist layer on the negative electrode active material layer;
performing a negative patterning process on the photoresist layer to form a negative pattern on the negative electrode active material layer; and
selectively removing the photoresist layer.

2. The method of claim 1, wherein the forming the negative pattern comprises performing roll pressing.

3. The method of claim 1, wherein the forming the photoresist layer comprises coating a photoresist composition, and
wherein the photoresist composition comprises at least one of a photoresist resin, a photo-acid generator, a quencher, an additive, and a solvent.

4. The method of claim 1, wherein a ratio (d/P) of a maximum depth (d) of the negative pattern to a thickness (P) of the photoresist layer is greater than 0 and less than or equal to about 1.

5. The method of claim 1, wherein the negative pattern has a triangular shape.

6. The method of claim 1, wherein the negative pattern has a multi-hole shape.

7. The method of claim 6, wherein the multi-hole shape comprises:
a first triangular shape; and
a second triangular shape on one side of the first triangular shape,
wherein a size of the second triangular shape is smaller than a size of the first triangular shape.

8. A negative electrode for a rechargeable lithium battery, the negative electrode comprising:
a negative electrode current collector;
a negative electrode active material layer on the negative electrode current collector; and
photoresist particles on a surface of the negative electrode active material layer,
wherein the negative electrode active material layer comprises a negative pattern formed on an upper portion of the negative electrode active material layer.

9. The negative electrode of claim 8, wherein an area density of the photoresist particles on the surface of the negative electrode active material layer is greater than 0 and less than or equal to about 0.05 cm².

10. The negative electrode of claim 8, wherein at least a plurality of the photoresist particles comprises a photoresist resin and a photo-acid generator.

11. The negative electrode of claim 8, wherein the negative electrode active material layer further comprises a non-negative pattern, and
wherein the photoresist particles are on a surface of the negative pattern and on a surface of the non-negative pattern.

12. The negative electrode of claim 11, wherein a density of the photoresist particles on the surface of the negative pattern is greater than the density of the photoresist particles on the surface of the non-negative pattern.

13. The negative electrode of claim 8, wherein a ratio (d/D) of a maximum depth (d) of the negative pattern to a thickness (D) of the negative electrode active material layer is greater than 0 and less than or equal to about 0.1.

14. The negative electrode of claim 8, wherein the negative pattern has a triangular shape.

15. The negative electrode of claim 8, wherein the negative pattern has a multi-hole shape.

16. The negative electrode of claim 15, wherein the multi-hole shape comprises:
a first triangular shape; and
a second triangular shape on one side of the first triangular shape,
wherein a size of the second triangular shape is smaller than a size of the first triangular shape.

17. A rechargeable lithium battery comprising:
a positive electrode;
the negative electrode according to claim 8; and
a separator between the positive electrode and the negative electrode.

18. The rechargeable lithium battery of claim 17, wherein the negative pattern of the negative electrode active material layer is adjacent to the separator.

19. The rechargeable lithium battery of claim 17, wherein the positive electrode active material comprises a lithium transition metal composite oxide.

20. The rechargeable lithium battery of claim 17, further comprising a liquid electrolyte.
